(19) United States
(12) Patent Application Publication
(10) Pub. No.: US 2006/0231906 A1
(43) Pub. Date: Oct. 19, 2006

(54) Structure for measuring gate misalignment and measuring method thereof

(75) Inventors: Young-gun Ko, Seongnam-si (KR); Ja-hum Ku, Seongnam-si (KR)

Correspondence Address: F. CHAU & ASSOCIATES, LLC, 130 WOODBURY ROAD, WOODBURY, NY, 11797, US

(73) Assignee: SAMSUNG ELECTRONICS CO., LTD.

(21) Appl. No.: 11/254,081

(22) Filed: Oct. 19, 2005

Related U.S. Application Data
(60) Provisional application No. 60/671,627, filed on Apr. 15, 2005.

(51) Int. Cl. H01L 29/76

(52) U.S. Cl. 257/401

(57) ABSTRACT

Provided are an improved structure for measuring gate misalignment and a measuring method thereof. The structure includes an active region and a device isolation region, a first gate group including a plurality of gates extending in one direction at one side of the active region, widths of the gates being the same with one another and lengths of the respective gates overlapping with the active region being different from one another, and a second gate group including a plurality of gates extending in one direction at the other side of the active region, widths of the gates being the same as one another and lengths of the respective gates overlapping with the active region being different from one another.

### BACKGROUND OF THE INVENTION

1. Field of the Invention

The present invention relates to a structure for measuring gate misalignment and a measuring method thereof. More particularly, the present invention relates to an improved structure for measuring gate misalignment and a measuring method thereof.

2. Description of the Related Art

With the reduction of the design rule of a semiconductor device, it is necessary to fabricate as many transistors as possible within a narrow area, and thus accurately aligning a gate and the active area is an important factor to ensure enhanced operating performance of a semiconductor device.

Conventionally, an optical sensing equipment has been used to measure and monitor misalignment between gates and the active area. Such optical measurement requires a prolonged measuring time, defining of measurement points, with an increased probability of measurement errors due to operator's mistake. In addition, the optical measurement is not suitable for statistical analysis because it is quite difficult to collect multiple data samples by monitoring multiple semiconductor substrates. Therefore, to overcome such limitations, there exists a need for development of gate misalignment measuring structures based on electrical measurements.

### SUMMARY OF THE INVENTION

The present invention provides a structure for measuring gate misalignment with enhanced measurement reliability.

The present invention also provides a method for measuring gate misalignment with enhanced measurement reliability.

The above stated object as well as other objects, features and advantages, of the present invention will become clear to those skilled in the art upon review of the following description.

According to an aspect of the present invention, there is provided a gate misalignment measuring structure including a semiconductor substrate including an active region and a device isolation region, a first gate group including a plurality of gates extending in one direction at one side of the active region, widths of the gates being the same with one another and lengths of the respective gates overlapping with the active region being different from one another, and a second gate group including a plurality of gates extending in one direction at the other side of the active region, widths of the gates being the same with one another and lengths of the respective gates overlapping with the active region being different from one another, wherein the lengths of the gates of the first gate group overlapping with the active region are the same lengths as the corresponding gates of the second gate group.

According to another aspect of the present invention, there is provided a method for measuring gate misalignment including providing a gate misalignment measuring structure comprising a semiconductor substrate including an active region and a device isolation region, a first gate group including a plurality of gates extending in one direction at one side of the active region, widths of the gates being the same with one another and lengths of the respective gates overlapping with the active region being different from one another, and a second gate group including a plurality of gates extending in one direction at the other side of the active region, widths of the gates being the same with one another and lengths of the respective gates overlapping with the active region being different from one another, wherein the lengths of the gates of the first gate group overlapping with the active region are the same as the lengths of the corresponding gates of the second gate group, measuring gate leakage current levels of the plurality of gates of the first and second gate group, generating a first straight line which graphs length of the gates overlapping with the active region when the gates are normally aligned versus gate leakage current levels of the respective gates of either the first or second gate group, and generating a second straight line in which the graphs length of the gates overlapping with the active region when the gates are normally aligned versus the average gate leakage current levels of the gates of the first gate group and the gates of the second gate group corresponding to the respective gates of the first gate group and determining the misalignment distance by calculating the horizontal offset between the first and second straight lines.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic layout view of a structure for measuring gate misalignment according to an embodiment of the present invention;

FIG. 2 is a sectional view of the structure for measuring gate misalignment, shown in FIG. 1 taken along the line II-II′;

FIG. 3 is a layout view illustrating that gates are misaligned by a predetermined distance, as measured by the gate misalignment measuring structure shown in FIG. 1;

FIG. 4 is a flow chart illustrating a method of measuring gate misalignment according to an embodiment of the present invention;

FIG. 5 is a diagram illustrating intermediate steps S530 and S540 shown in FIG. 4;

FIG. 6 is a schematic layout view of a structure for measuring gate misalignment according to another embodiment of the present invention; and

FIG. 7 is a schematic layout view of a structure for measuring gate misalignment according to still another embodiment of the present invention.

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

The present invention will now be described more fully with reference to the accompanying drawings, in which an exemplary embodiment of the invention is shown.

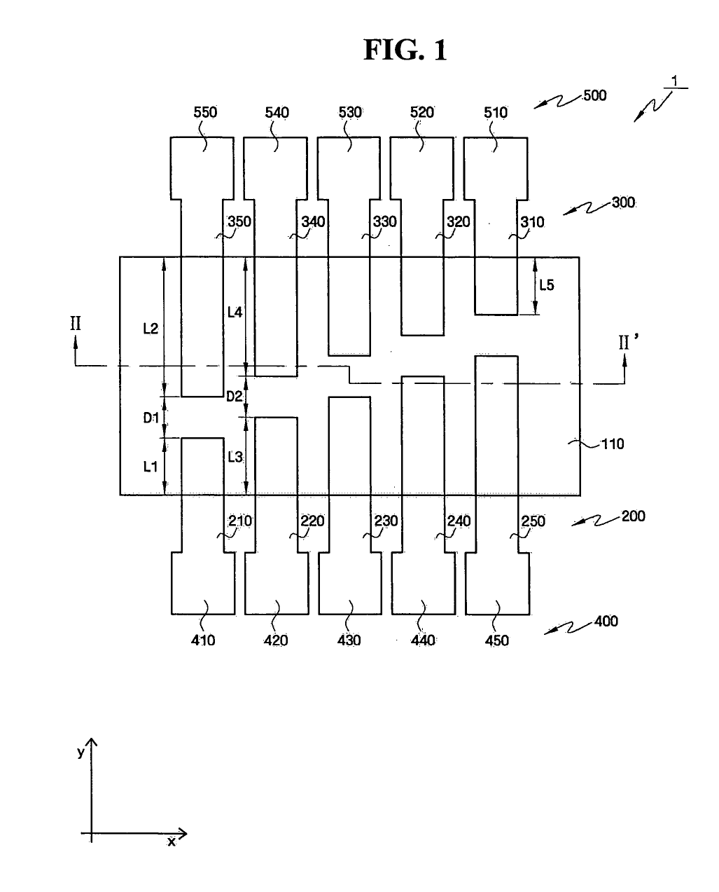

Structures for measuring gate misalignment according to the present invention and measuring methods thereof will now be described with reference to FIGS. 1 through 7.

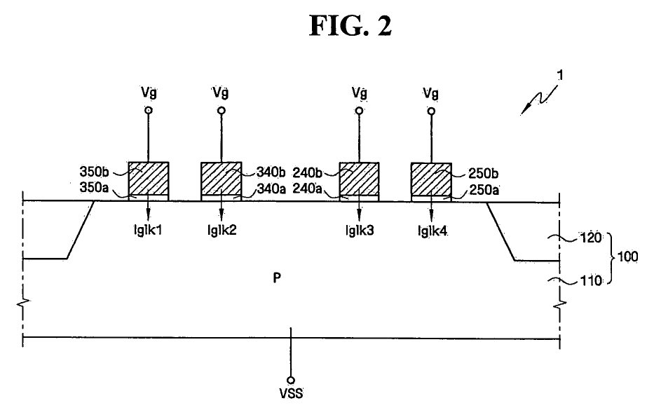

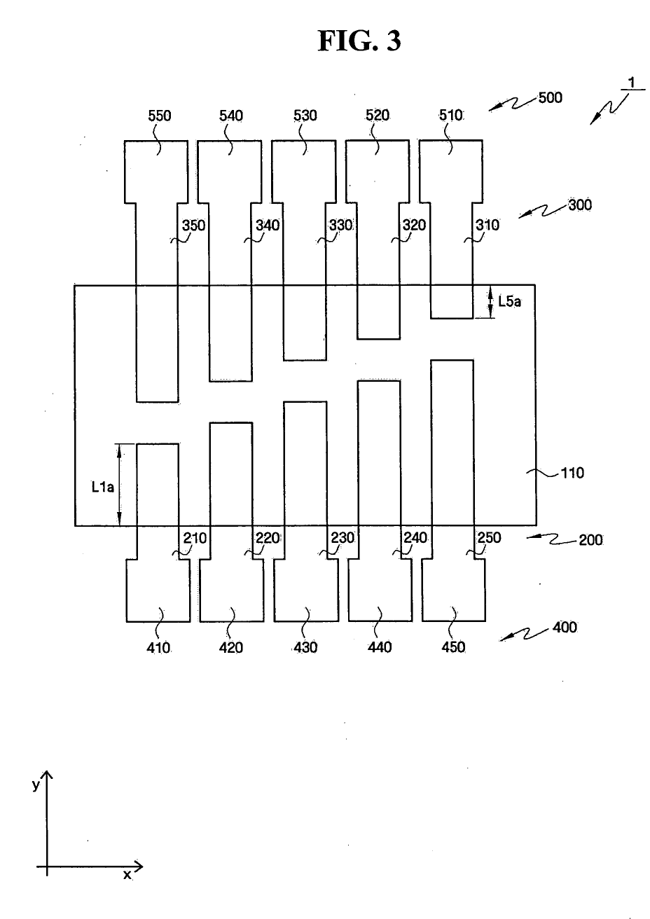

FIG. 1 is a schematic layout view of a structure for measuring gate misalignment according to an embodiment of the present invention, FIG. 2 is a sectional view of the structure for measuring gate misalignment, shown in FIG. 1 taken along the line II-II′, and FIG. 3 is a layout view illustrating that gates are misaligned by a predetermined distance, as measured by the gate misalignment measuring structure shown in FIG. 1.

Referring to FIGS. 1 and 2, a gate misalignment measuring structure 1 according to an embodiment of the present invention includes semiconductor substrate 100, a first gate group 200, a second gate group 300, a first pad group 400, and a second pad group 500.

The semiconductor substrate 100 is made of at least one semiconductor material selected from the group consisting of Si, Ge, SiGe, GaP, GaAs, SiC, SiGeC, InAs and InP, and either a P-type or an N-type impurity-doped substrate may be used as the semiconductor substrate 100. A device isolation region 120 is formed in the semiconductor substrate 100 to define an active region 110. The device isolation region 120 may be generally formed by LOCOS (LOCal Oxidation of Silicon) technique to become a FOX (Field OXide) or STI (Shallow Trench Isolation) region. As shown in FIG. 1, a P-type substrate is employed for the semiconductor substrate 100 and a STI is employed for the device isolation region 120.

A predetermined voltage, e.g., a ground voltage VSS, is applied to the semiconductor substrate 100.

The first and second gate groups 200 and 300 include the plurality of gates 210-250 and 310-350, respectively. Here, the plurality of gates 210-250 and 310-350 include gate insulation layers 240a, 250a, 340a and 350a formed on the semiconductor substrate 100, and conductive layer patterns 240b, 250b, 340b and 350b formed on gate insulation layers 240a, 250a, 340a and 350a, respectively, as shown in FIG. 2.

The first gate group 200 includes a plurality of gates 210-250 formed at one side of the active region 110 in one direction, that is, in the y-axis direction. Specifically, the plurality of gates 210-250 are formed to intersect the active region 110 and the device isolation region 120, and even when the plurality of gates 210-250 are misaligned in an extending direction, i.e., the y-axis direction, the plurality of gates 210-250 are long enough to overlap with the active region 110. In particular, the plurality of gates 210-250 overlap with the active region 110 by different lengths L1 and L3 and have the same width as one another.

The second gate group 300 corresponds to the respective gates 210-250 of the first gate group 200, and includes the plurality of gates 310-350 extending in one direction from the other side of the active region 110, i.e., the y-axis direction. For example, the gate 210 of the first gate group 200 corresponds to the gate 310 of the second gate group 300, and the gate 220 of the first gate group 200 corresponds to the gate 320 of the second gate group 300.

In addition, even when the plurality of gates 310-350 of the second gate group 300 are formed to intersect the active region 110 and the device isolation region 120 and misaligned in an extending direction, i.e., the y-axis direction, the plurality of gates 310-350 are long enough to come into contact with the active region 110. In particular, the plurality of gates 310-350 overlap with the active region 110 by different lengths L2, L4, and L5, respectively, and widths of the plurality of gates 310-350 are the same as one another. Further, the widths of the plurality of gates 310-350 are the same with those of the plurality of gates 210-250 of the first gate group 200.

When the gates 210-250 of the first gate group 200 and their corresponding gates 310-350 of the second gate group 300 are normally aligned without being misaligned, the lengths e.g., L1 and L5, of the gates overlapping with the active region 110 are substantially the same with each other.

In an embodiment of the present invention, the respective gates 210-250 of the first gate group 200 are arranged opposite to and facing the respective gates 310-350 of the second gate group 300, but the invention is not limited to this arrangement. Here, the respective gates 210-250 and 310-350 opposite to and facing each other are complementary in their lengths. Thus, the sum of lengths of the gates 210-250 of the first gate group 200 overlapping with the active region 110 in the gates 310-350 of the second gate group 300 is kept constant. For example, the gate 210 of the first gate group 200 and the gate 350 of the second gate group 300 are opposite to and face each other, and the gate 220 of the first gate group 200 and the gate 340 of the second gate group 300 are opposite to and face each other. A sum of the length L1 of the gate 210 overlapping with the active region 110 and the length L2 of the gate 350 overlapping with the active region 110 is the same as the sum of the length L3 of the gate 220 overlapping with the active region 110 and the length L4 of the gate 340 overlapping with the active region 110 are the same with each other.

In addition, the respective gates 210-250 of the first gate group 200 are equidistantly spaced apart from the corresponding gates 310-350 of the second gate group 300 opposite to and facing the plurality of gates 210-250 of the first gate group 200. For example, distance D1 between the gate 210 of the first gate group 200 and the gate 350 of the second gate group 300 is equal to a distance D2 between the gate 220 of the first gate group 200 and the gate 340 of the second gate group 300.

Further, as shown in FIG. 1, the plurality of gates 210-250 of the first gate group 200 arranged in an ascending order of the gate lengths 210-250 overlapping with the active region 110, and the plurality of gates 310-350 of the second gate group 300 are arranged in a descending order of gate lengths 310-350 overlapping with the active region 110. Such arrangement of gates 210-250 and gates 310-350 enables the same to be arranged in a narrow area. Here, if there is no limitation in an area where gates 210-250 and gates 310-350 of the first and second groups 200 and 300 are to be formed, a variety of gate arrangements may be implemented.

The first pad group 400 is connected to each of the plurality of gates 210-250 of the first gate group 200 and includes a plurality of pads 410-450 having a predetermined gate voltage Vg applied thereto. The second pad group 500 is connected to each of the plurality of gates 310-350 of the second gate group 300 and includes a plurality of pads 510-550 having the predetermined gate voltage Vg applied thereto. Here, the gate voltage Vg, e.g., 1.5 V, may vary according to the semiconductor device to which the gate voltage Vg is applied.

The gate misalignment measuring structure 1 according to an embodiment of the present invention operates based on the following measurement principle, which will now be described.

In the present invention, as shown in FIG. 2, the gate misalignment measuring structure 1 determines the misalignment distance using gate leakage current levels Iglk1, Iglk2, Iglk3, and Iglk4 flowing from conductive layer patterns 240b, 250b, 340b, 350b to the semiconductor substrate 100 through gate insulation layers 240a, 250a, 340a and 350a. For example, if the gate voltage Vg is applied to the pad 450 corresponding to the gate 250, the gate leakage current Iglk4 flows from the conductive layer pattern 250b to the semiconductor substrate 100.

Referring back to FIG. 1, the amount of the gate leakage current is proportional to an overlapped area where the gates 210-250 and 310-350 overlap with the active region 110. Thus, in an embodiment of the present invention, while the plurality of gates 210-250 and 310-350 of the first and second gate groups 200 and 300 have the same gate width, the lengths L1 through L5 of the gates overlapping with the active region 110 are different from one another. Thus, the gate leakage current is proportional to the length of the gate overlapping with the active region 110.

As shown in FIG. 1, in measuring the gate leakage current levels of the plurality of gates 210-250 and 310-350, the plurality of gates 210-250 of the first gate group 200 arranged in an ascending order of the lengths of the gates 210-250 overlapping with the active region 110, and the plurality of gates 310-350 of the second gate group 300 are arranged in a descending order of lengths of the gates 310-350 overlapping with the active region 110. Therefore, the gate leakage current levels of the plurality of gates 210-250 increase in order from 210 to 250 and the gate leakage current levels of the plurality of gates 310-350 increase in order from 310 to 350.

In a case where the plurality of gates 210-250 and 310-350 are not misaligned but normally aligned, the gate leakage current levels of the gates 210-250 of the first gate group 200 overlapping with the active region 110 are substantially the same as the gate leakage current levels of the gates 310-350 of the second gate group 300 corresponding to the gates 210-250 of the first gate group 200. This is because the length of each of the gates 210-250 is the same as that of each of the gates 310-350.

In addition, even if the gates 210-250 and 310-350 are misaligned, the sum of the leakage current level of each of the gates 210-250 of the first gate group 200 and the leakage current level of each of the gates 310-350 of the second gate group 300 overlapping with the active region 110 is kept constant. That is, as shown in FIG. 3, when the gates 210-250 and 310-350 are misaligned in the y-axis direction, the length L1 of the gate 210 overlapping with the active region 110 increases to a length L1a, while the length L5 of the gate 310 overlapping with the active region 110 decreases to a length L5a. This is because an increment (L1a-L1) is substantially the same as a decrement (L5-L5a):

Therefore, since the average of the leakage current level of each of the gates 210-250 of the first gate group 200 and the leakage current level of each of the gates 310-350 of the second gate group 300 corresponding to the gates 210-250 of the first gate group 200, which is referred to as an ‘average gate leakage current’ hereinbelow, is kept constant irrespective of whether the gates are misaligned or not, the average gate leakage current can be used as a reference value. In more detail, if the gates are misaligned, a gate leakage current level of one of the gates 210-250, 310-350 of the first or second gate group 200, 300 is different from the average gate leakage current level. For example, as shown in FIG. 3, when y-axis misalignment occurs to the gates 210-250 and 310-350, the gate leakage current of the gate 210 of the first gate group 200 is considerably larger than the average gate leakage current.

if a reference is directly taken from the gate misalignment measuring structure 1, the reference reflects various processing variables that may be encountered during the practical fabrication process of the gate. Thus, the reference contains the processing variables contained in the gate leakage current levels of the respective gates of the first or second gate group 200, 300, thereby measuring the misaligned distance more accurately.

Conclusively, the gate misalignment measuring structure 1 measures misalignment based on the following principle in which the gate leakage current levels of the plurality of gates 210-250 of the first gate group 200 or the gate leakage current levels of the plurality of the second gate group 300 are proportional to widths of the gates 210-250 and 310-350 overlapping with the active region 110. The misalignment distance is determined by measuring the gate leakage currents of the gates 210-250, 310-350 extending in one direction of the active region 110. Particularly, since the respective gates 210-250 of the first gate group 200 and their corresponding gates 310-350 of the second gate group 300 are provided at both sides of the active region 110, respectively, the measurement accuracy can be further increased using the average gate leakage current level of the gates 210-250 and 310-350 of the first and second gate groups 200 and 300.

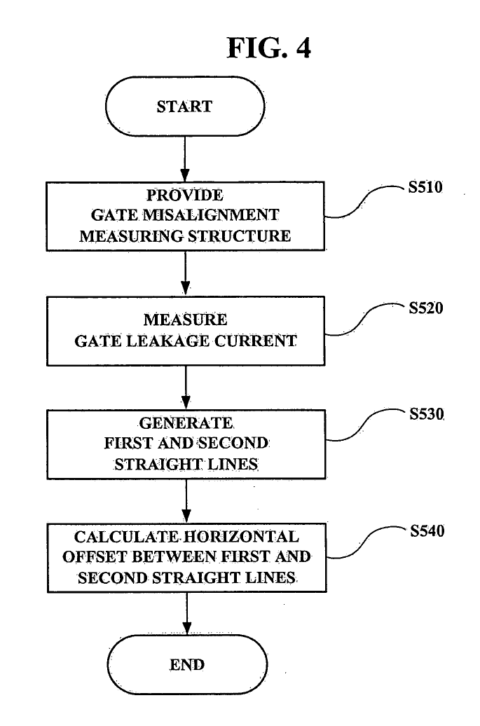

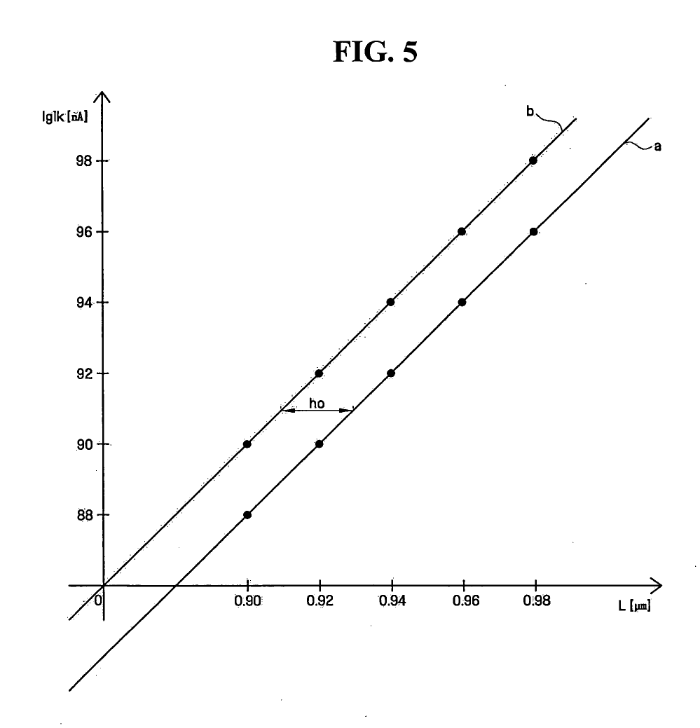

FIG. 4 is a flow chart illustrating a method of measuring gate misalignment according to an embodiment of the present invention, and FIG. 5 is a diagram illustrating intermediate steps S530 and S540 shown in FIG. 4. For descriptive convenience, the first and second gate groups 200 and 300, which are misaligned by a predetermined distance in the y-axis direction like in FIG. 3, will now be described by way of example.

Referring to FIGS. 3 and 4, the gate misalignment measuring structure 1 is first provided in operation S510.

Specifically, the gate misalignment measuring structure 1 includes a semiconductor substrate 100, a first gate group 200, and a second gate group 300. The semiconductor substrate 100 has an active region 110 and a device isolation region 120. The first gate group 200 includes a plurality of gates 210-250 extend in one direction, i.e., the Y-axis direction, at one side of the active region 110, widths of the gates 210-250 are the same with one another and lengths of the respective gates 210-250 overlapping with the active region 110 are different from one another. The second gate group 300 include a plurality of gates 310-350 extending in one direction at the other side of the active region 110, widths of the gates 310-350 are the same as one another and lengths of the respective gates 310-350 overlapping with the active region 110 being different from one another. When the gates 210-250 of the first gate group 200 and their corresponding gates 310-350 of the second gate group 300 are normally aligned, the lengths of the gates 210-250 of the first gate group 200 overlapping with the active region 110 are the same as the lengths of the corresponding gates 310-350 of the second gate group 300.

Next, gate leakage current levels of the plurality of gates 210-250 and 310-350 of the first and second gate groups 200 and 300 are measured in operation S520.

Concretely, at least two pairs of the gates 210-250 and 310-350 of the first and second gate groups 200 and 300, e.g., (410, 510) and (420, 520), are subjected to measurement of misalignment. Of course, the more the gates 210-250 and 310-350 of the first and second gate groups 200 and 300 are subjected to measurement, the more accurately the misaligned distance can be measured. In a case of measuring the gate leakage current levels of the gate 210 of the first gate group 200 and the gate 310 of the second gate group 300, a predetermined gate voltage, e.g., Vg, is applied to a pad 410 of a first pad group 400 and a pad 510 of a second pad group 500, followed by measuring gate leakage current levels leaking to the semiconductor substrate 100 via a gate insulation layer.

As described above, the gate leakage current level is proportional to a length of a gate overlapping with the active region 110 of the plurality of gates 210-250 and 310-350. Thus, gate leakage current levels of the plurality of gates 210-250 of the first gate group 200 increase gradually in an order from 210 to 250, while gate leakage current levels of the plurality of gates 310-350 of the second gate group 300 increase gradually in order from 310 to 350.

In operation S530, first and second straight lines are generated.

Referring to FIG. 5, the x-axis indicates lengths of the gates 210-250, 310-350 of the first or second gate group 200, 300 overlapping with the active region 110 when the respective gates 210-250, 310-350 are normally aligned, and the y-axis indicates gate leakage current levels.

First, points are marked on the x-y plane of the respective gates 310-350, the points represent length of the gates overlapping with the active region 110 when the gates 210-250, 310-350 are normally aligned versus gate leakage current levels of the respective gates of either the first or second gate group 200, 300, e.g., the second gate group 300.

For example, when the gate 310 of the second gate group 300 is normally aligned, the overlapped length with respect to the active region 110 is 0.90 μm and the gate leakage current level is 88 nA. In this way, points are marked on the x-y plane and connected to generate a first straight line indicated by ‘a’. In FIG. 5, if the first straight line a, satisfies the relationship y=100x−2. On the other hand, if the points marked on the x-y plane are not connected by a straight line, the first straight line a may be generated through linear regression analysis.

Next, the average of the gate leakage current levels of the gates 210-250 and 310-350 of the first and second gate groups 200 and 300 is calculated. The lengths of the gates which overlap with the active region when the gates are normally arranged versus the calculated average gate leakage current are marked on the x-y plane. As described above, since the average of the leakage current level of each of the gates 210-250 of the first gate group 200 and the leakage current level of each of the gates 310-350 of the second gate group 300 corresponding to the gates 210-250 of the first gate group 200 is kept constant irrespective of whether the gates 210-250 and the gates 310-350 are misaligned or not, the average gate leakage current may be considered as the gate leakage current level exhibited when no misalignment occurs to any of the gates 210-250 and the gates 310-350. For example, when the gate 210 of the first gate group 200 is normally aligned, the overlapped length with respect to the active region 110 is 0.90 μm and the gate leakage current level is 92 nA. Accordingly, the average of gate leakage current levels of the gate 210 of the first gate group 200 and the gate 310 of the second gate group 300 is 0.90 nA. In this way, points are marked on the x-y plane and connected to generate a second straight line b. In FIG. 5, the second straight line b satisfies the relationship y=100x. However, if points on the x-y plane are not connected to generate a straight line, the second straight line b may be generated through linear regression analysis.

Referring back to FIG. 4, a horizontal offset ‘ho’ between the first and second straight lines a and b is obtained to determine the misaligned distance in operation S540.

In more detail, since the first straight line a represents gate leakage current levels exhibited when the second straight line b is misaligned by a predetermined distance, the horizontal offset ‘ho’ shown in FIG. 5 is obtained to determine the misalignment distance. For example, the horizontal offset ho is obtained by calculating a distance between x-intercepts of the first and second straight lines a and b. Since the x-intercept of the first straight line a is 0.02 μm and the x-intercept of the second straight line b is 0, the misaligned distance is 0.02 μm.

As described above, electrical measurement enables a measuring time to be reduced without having to define measurement points. In addition, a probability of incorrect results due to operator's mistake can be prevented. Further, since the measuring method is simple, it can be suitably employed for collecting multiple statistical data by monitoring multiple semiconductor substrates. In addition, since the reference reflects various processing variables that may be encountered in a practical gate fabrication process, the misaligned distance can be measured more accurately.

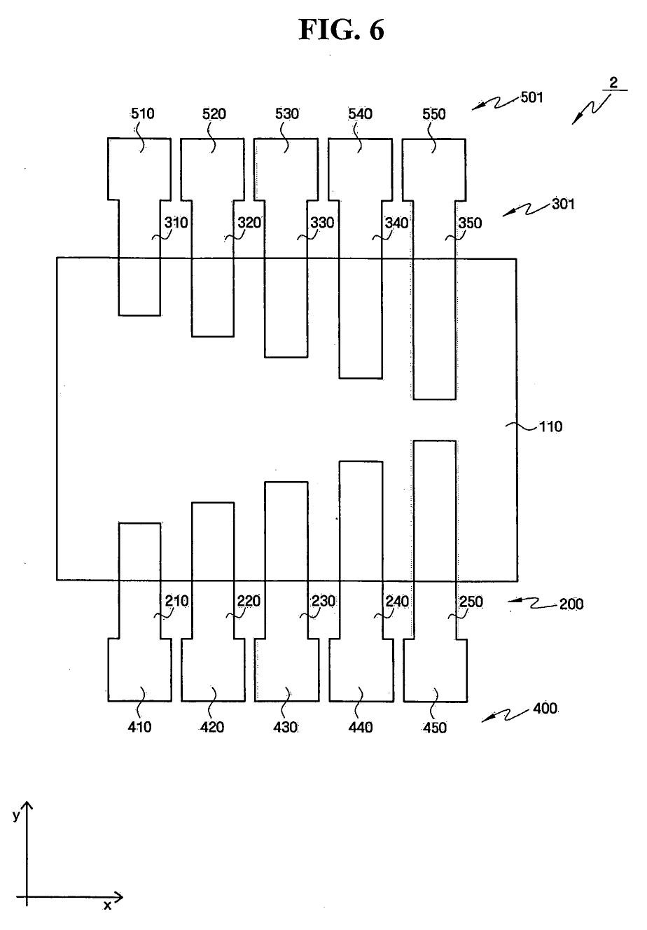

FIG. 6 is a schematic layout view of a structure 2 for measuring gate misalignment according to another embodiment of the present invention. Components having the same functions as those shown in FIG. 1 are identified by the same reference numerals, the components will not be described in further detail.

Referring to FIG. 6, in the gate misalignment measuring structure 2, if there is no limitation in the area where the first and second gate groups 200 and 301 are formed, the gates 210-250 of the first gate group 200 and the gates 310-350 of the second gate group 301 corresponding to the gates 210-250 of the first gate group 20 are arranged such that they are opposite to and face each other. Therefore, the gates of the first gate group 200 are opposite to and spaced apart at different distances from the respective gates 310-350, respectively. In other words, the plurality of gates 210-250 of the first gate group 200 and the plurality of gates 310-350 of the second gate group 300 are arranged in an ascending order in terms of lengths of the gates 310-350 overlapping with the active region 110.

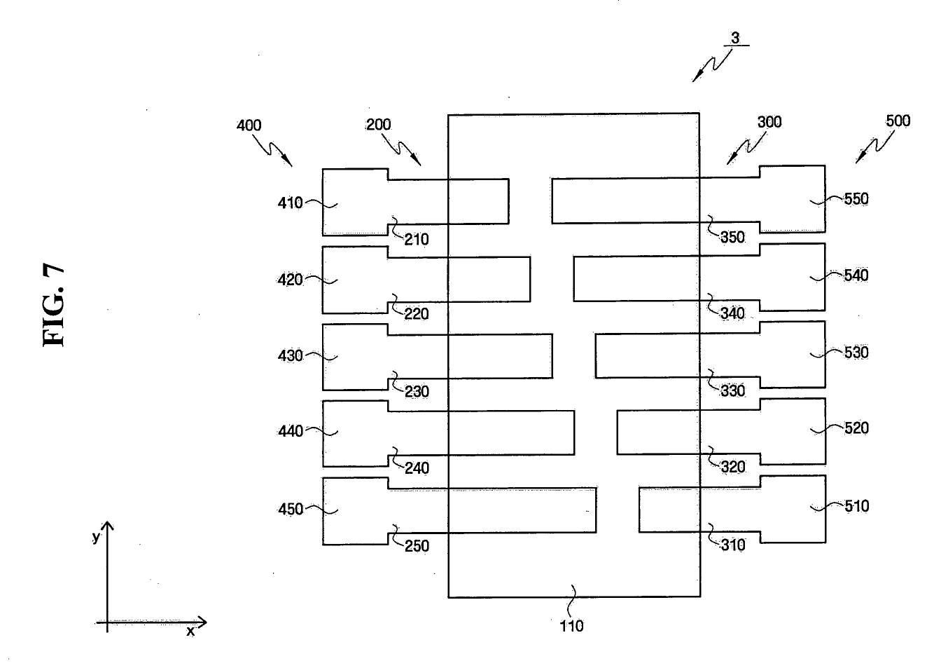

FIG. 7 is a schematic layout view of a structure 3 for measuring gate misalignment according to still another embodiment of the present invention. Components having the same functions as those shown in FIG. 1 are identified by the same reference numerals, the components will not be described in further detail.

Referring to FIG. 7, the gate misalignment measuring structure 3 is capable of measuring the misaligned distance in the x-axis direction. This is because the gates 210-250 and 310-350 of the first and second gate groups 200 and 300 extend in the x-axis direction.

Although not shown, the gates of the first and second gate groups may elongate in a diagonal direction. In such an instance, it is obvious to one skilled in the art that a misaligned distance can be measured in a diagonal direction.

The gate misalignment measuring structure and method according to the present invention provide at least the following advantages.

First, an electrical method of gate misalignment requires reduced measuring time without defining measurement points. In addition, measurement reliability can be enhanced by preventing the probability of incorrect results due to operator's mistake.

Second, since the measuring method is simple, it can be suitably employed for collecting multiple statistical data by monitoring multiple semiconductor substrates.

Third, since the reference reflects various processing variables that may be encountered during the practical gate fabrication process, the misaligned distance can be measured more accurately.

While the present invention has been particularly shown and described with reference to exemplary embodiments thereof, it will be understood by those of ordinary skill in the art that various changes in form and details may be made therein without departing from the spirit and scope of the present invention as defined by the following claims. Therefore, it is to be understood that the above-described embodiments have been provided only in a descriptive sense and will not be construed as placing any limitation on the scope of the invention.

What is claimed is:

1. A gate misalignment measuring structure comprising:
a semiconductor substrate including an active region and a device isolation region;
a first gate group including a plurality of gates extending in one direction at one side of the active region, widths of the gates being the same with one another and lengths of the respective gates overlapping with the active region being different from one another; and
a second gate group including a plurality of gates extending in one direction at the other side of the active region, widths of the gates being the same as one another and lengths of the respective gates overlapping with the active region being different from one another,
wherein the lengths of the gates of the first gate group overlapping with the active region are substantially the same with the lengths of the corresponding gates of the second gate group.

2. The gate misalignment measuring structure of claim 1, wherein the plurality of gates of the first gate group are opposite to and face the plurality of gates of the second gate group.

3. The gate misalignment measuring structure of claim 2, wherein the plurality of gates of the first gate group and the plurality of gates of the second gate group opposite to and facing the gates of the first gate group are complementary in their lengths.

4. The gate misalignment measuring structure of claim 3, wherein the plurality of gates of the first gate group are equidistantly spaced from the plurality of gates of the second gate group opposite to and facing the plurality of gates of the first gate group.

5. The gate misalignment measuring structure of claim 3, wherein the plurality of gates of the first gate group are arranged in ascending order of the lengths of the gates overlapping with the active region, and the plurality of gates of the second gate group are arranged in a descending order of lengths of the gates overlapping with the active region

6. The gate misalignment measuring structure of claim 1, further comprising:
a first pad group having a plurality of pads connected to the plurality of gates of the first gate group, respectively, and applying a predetermined voltage to the plurality of gates of the first gate group; and
a second pad group having a plurality of pads connected to the plurality of gates of the second gate group, respectively, and applying a predetermined voltage to the plurality of gates of the second gate group.

7. A method for measuring gate misalignment comprising:
providing a gate misalignment measuring structure comprising a semiconductor substrate including an active region and a device isolation region, a first gate group including a plurality of gates extending in one direction at one side of the active region, widths of the gates being the same with one another and lengths of the respective gates overlapping with the active region being different from one another, and a second gate group including a plurality of gates extending in one direction at the other side of the active region, widths of the gates being the same with one another and lengths of the respective gates overlapping with the active region being different from one another, wherein the lengths of the gates of the first gate group overlapping with the active region are substantially the same with the lengths of the corresponding gates of the second gate group;
measuring gate leakage current levels of the plurality of gates of the first and second gate group;
generating a first straight line which graphs length of the gates overlapping with the active region when the gates are normally aligned versus gate leakage current levels of the respective gates of either the first or second gate group, and generating a second straight line which graphs length of the gates overlapping with the active region when the gates are normally aligned versus the average gate leakage current levels of the gates of the first gate group and the gates of the second gate group corresponding to the respective gates of the first gate group; and
determining the misalignment distance by calculating a horizontal offset between the first and second straight lines.

8. The method of claim 7, wherein in the generating of the first and second straight lines, the first and second straight lines are generated by linear regression analysis.

9. The method of claim 7, wherein the first and second straight lines are formed on the x-y plane, in which the x-axis indicates length of the gates overlapping with the active region when the gates are normally aligned, and the y-axis indicates gate leakage current levels, and the horizontal offset between the first and second straight lines is equal to the distance between x-intercepts of the first and second straight lines.

10. The method of claim 9, wherein the plurality of gates of the first gate group are opposite to and face the plurality of gates of the second gate group.

11. The method of claim 10, wherein the plurality of gates of the first gate group and the plurality of gates of the second gate group opposite to and facing the gates of the first gate group are complementary in their lengths.

12. The method of claim 11, wherein the plurality of gates of the first gate group are equidistantly spaced apart from the plurality of gates of the second gate group opposite to and facing the plurality of gates of the first gate group.

13. The method of claim 11, wherein the plurality of gates of the first gate group are arranged in an ascending order of the lengths of the gates overlapping with the active region, and the plurality of gates of the second gate group are arranged in a descending order of lengths of the gates overlapping with the active region

14. The method of claim 7, wherein the providing the gate misalignment measuring structure, the gate misalignment measuring structure further comprising a first pad group having a plurality of pads connected to the plurality of gates of the first gate group, respectively, and applying a predetermined voltage to the plurality of gates of the first gate group, and a second pad group having a plurality of pads connected to the plurality of gates of the second gate group, respectively, and applying a predetermined voltage to the plurality of gates of the second gate group.
